(19) United States
(12) Patent Application Publication
(10) Pub. No.: US 2018/0009073 A1
(43) Pub. Date: Jan. 11, 2018

(54) MICRO HEAT PIPE AND METHOD OF MANUFACTURING MICRO HEAT PIPE

(71) Applicant: ACMECOOLS TECH. LTD., Tortola (VG)

(72) Inventor: Chi-Te CHIN, TAICHUNG CITY (TW)

(21) Appl. No.: 15/710,115

(22) Filed: Sep. 20, 2017

Related U.S. Application Data
(62) Division of application No. 14/929,972, filed on Nov. 2, 2015.

(51) Int. Cl. B23P 15/26; H01L 21/48; H01L 23/427; F28D 15/04

(52) U.S. Cl. CPC B23P 15/26; F28D 15/046; H01L 21/4871; H01L 23/427; F28F 2255/18; B23P 2700/09; F28F 2260/00

(57) ABSTRACT

A micro heat pipe includes a pipe body, a second capillary structure disposed inside the pipe body, and a working fluid injected into the pipe body. The pipe body has two enclosed ends and is defined with a heat absorbing section, a heat isolating section and a condensing section. The pipe body is provided on an inner pipe wall thereof with etched patterns serving as a first capillary structure and fully distributed in the aforementioned sections. The heat absorbing section is filled up with the second capillary structure. The micro heat pipe is manufactured in a way that the inner pipe wall of the pipe body is etched to form the first capillary structure, the second capillary structure is filled in the heat absorbing section and then sintered, the working fluid is injected into the pipe body, and the pipe body is vacuumed and sealed.

### CROSS-REFERENCE TO RELATED APPLICATIONS

This application is a Divisional of co-pending application Ser. No. 14/929,972 filed on Nov. 2, 2015, for which priority is claimed under 35 U.S.C. §120; the entire contents of which are hereby incorporated by reference.

### BACKGROUND

### 1. Technical Field

The present disclosure relates to a heat dissipating device, and more particularly to a micro heat pipe and a method of manufacturing the same.

### 2. Description of Related Art

A heat pipe generally includes an enclosed pipe, a capillary structure disposed inside the enclosed pipe and formed by copper powder or metal mesh, and a working fluid filled in the enclosed pipe. Taiwan patent No. 1447342 discloses a heat pipe having a composite capillary structure which is resulted from that the heat pipe is provided with an interior second pipe body having an additional capillary structure formed by copper powder and grooves. Taiwan patent No. M499544 discloses a heat pipe having a plurality of capillary tissues.

However, the known heat pipes, including the heat pipes disclosed in the aforesaid two patents, just have a 6 mm diameter. At present, no stable and effective technology can be used to manufacture the heat pipe having a diameter smaller than 3 mm. The heat pipe having the diameter smaller than 3 mm is defined as the micro heat pipe in the present invention. Currently, there are many reasons why the known technology cannot be used to successfully manufacture the heat pipe having the diameter smaller than 3 mm, and two of the reasons are described below. The first reason is that the existing method of forming the capillary structure is to sinter copper powder or dispose copper mesh on the pipe wall, or forming the grooves on the pipe wall by tube extrusion, and even use composite configuration (such as the two aforesaid patents). Because of the limitation of the space inside the micro heat pipe, it is very difficult and unpractical to dispose the copper powder or the copper mesh to form the capillary structure inside the micro heat pipe by the existing method. In addition, the applied post-process (such as bending and flattening process) may directly break the capillary structure, and it makes the working fluid hard to be smoothly guided backwards to a heat absorbing section of the heat pipe, which results in failure of the function of the heat pipe. In addition, some conventional heat pipes have the capillary structure formed by grooves. The grooves may be unlike the copper powder or the copper mesh not to occupy the space inside the heat pipe and not to cause reduction of diameter of the space. However, the capillary structure formed by only grooves is hard to be processed as the pipe diameter become smaller. The aforesaid post-process may also damage the capillary structure and cause the blocking of the working fluid, and it makes the failure of function of the heat pipe. Regarding the second reason, the thin pipe structure of the micro heat pipe always have extremely thin pipe wall, so how to form an effective capillary structure on such thin pipe wall of the thin pipe body becomes an important issue. Currently, it is very hard to form the capillary structure inside the thin pipe body by manner of disposal of the grooves in the pipe, placement of copper powder or copper mesh in the pipe, or post-process, and no existing technology can effective solve this problem.

### SUMMARY

A primary objective of the present disclosure is to provide a micro heat pipe which is provided with etched patterns on an inner pipe wall thereof by etching. The etched patterns serve as a first capillary structure of the present disclosure, so it is not necessary to extra add a layer of copper powder or copper mesh on the inner pipe wall for forming the capillary structure, and the problem that inner space of the pipe is occupied by the capillary structure to cause reduction of the diameter can be prevented. In addition, the first capillary structure is composed of the etched patterns, so paths for guiding the working fluid backwards can have extremely high density to perform well capillary effect, and the working fluid can be effectively guided backwards.

A secondary objective of the present disclosure is to provide a micro heat pipe which can provide better paths for guiding the working fluid backwards than the conventional heat pipe having the capillary structure formed by only grooves.

To achieve the objectives, the present disclosure provides a micro heat pipe including a pipe body, a second capillary structure, and a working fluid. The pipe body has two enclosed ends and is defined along a body part thereof from one of the enclosed ends to the other enclosed end with a heat absorbing section, a heat isolating section and a condensing section. The pipe body is provided on an inner pipe wall thereof with etched patterns serving as a first capillary structure and fully distributed in the heat absorbing section, the heat isolating section and the condensing section. The second capillary structure is disposed inside the pipe body, and located in the heat absorbing section. The heat absorbing section is filled up with the second capillary structure which is capable of absorbing liquid by capillary action. The working fluid is injected into the pipe body.

The present disclosure uses the etching manner to form the etched patterns, which serve as the first capillary structure of the present disclosure, on the inner pipe wall, so it is not necessary to extra add a layer of copper powder or copper mesh on the inner pipe wall for forming the capillary structure, and the problem that inner space of the pipe is occupied by the capillary structure to cause reduction of the diameter can be prevented. In addition, the first capillary structure is composed of the etched patterns, so it can have high-density paths for guiding the working fluid backwards to perform well capillary effect, and the working fluid can be effectively guided backwards. In addition, the first capillary structure can provide better paths for guiding the working fluid backwards than the conventional heat pipe having the capillary structure formed by only grooves.

Another objective of the present disclosure is to provide a method of manufacturing a micro heat pipe, which is suitable to manufacture the micro heat pipe having a diameter smaller than 3 mm, and the micro heat pipe produced by the method can achieve the primary objective and the secondary objective.

To achieve the objective, the present disclosure provides a method of manufacturing a micro heat pipe, and the method includes the steps of: preparing a pipe body having two open ends, introducing etchant into the pipe body to etch an inner pipe wall of the pipe body to form etched patterns, which serve as a first capillary structure, on the inner pipe wall of the pipe body, sealing one of the two open ends of the pipe body by solderless welding, defining a heat absorbing section, a heat isolating section and a condensing section in order along a body part of the pipe body from the sealed end to the remained open end, disposing a second capillary material through the remained open end in the heat absorbing section of the pipe body in a way that the second capillary material fills up the heat absorbing section, sintering the second capillary material with the pipe body to make the second capillary material form a second capillary structure, introducing a working fluid into the pipe body, pumping air out of the pipe body to create a vacuum therein, and sealing the remained open end by solderless welding.

The aforesaid steps can be performed to manufacture the micro heat pipe having the diameter smaller than 3 mm, and the micro heat pipe produced can achieve the primary objective and the secondary objective.

### BRIEF DESCRIPTION OF THE DRAWINGS

FIG. 1 is a schematic planar view of a first preferred embodiment of the present disclosure.

FIG. 2 is a partially cut-away perspective view of the first preferred embodiment of the present disclosure.

FIG. 3 is a schematic planar view illustrating a using state of the first preferred embodiment of the present disclosure.

FIG. 4 is a schematic sectional view of a part of the first preferred embodiment of the present disclosure, illustrating regularly arranged etched patterns of a first capillary structure on an inner pipe wall of a pipe body.

FIG. 5 is another schematic sectional view of the part of the first preferred embodiment of the present disclosure, illustrating irregularly arranged etched patterns of the first capillary structure on the inner pipe wall of the pipe body.

FIG. 6 is another schematic sectional view of the first preferred embodiment of the present disclosure, illustrating a cross section of the pipe body having grooves.

FIG. 7 is a partially cut-away perspective view of a part of the first preferred embodiment of the present disclosure, illustrating the first capillary structure on the inner pipe wall of the pipe body having the grooves.

FIG. 8 is a schematic view of an appearance of the first preferred embodiment of the present disclosure.

FIG. 9 is a schematic view of another appearance of the first preferred embodiment of the present disclosure.

FIG. 10 is a schematic view of further another appearance of the first preferred embodiment of the present disclosure.

FIG. 11 is a flow chart of a second preferred embodiment of the present disclosure.

FIG. 12 is a schematic view illustrating a preparation step of the second preferred embodiment of the present disclosure.

FIG. 13 is a schematic view illustrating an etching step of the second preferred embodiment of the present disclosure.

FIG. 14 is a schematic view illustrating a sealing step for one open end of the second preferred embodiment of the present disclosure.

FIG. 15 is a perspective view illustrating a second capillary material placement step of the second preferred embodiment of the present disclosure.

FIG. 16 is a schematic view illustrating a sealing step for the other open end of the second preferred embodiment of the present disclosure.

FIG. 17 is another flow chart of the second preferred embodiment of the present disclosure.

### DESCRIPTION OF THE EXEMPLARY EMBODIMENTS

The technical features of the present invention will be fully understood from the detailed description of preferred embodiments given herein below and the accompanying drawings.

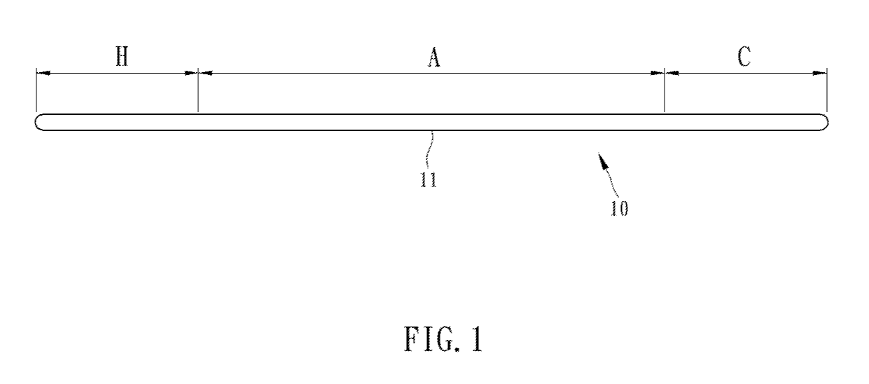

Referring to FIG. 1 through FIG. 3, a micro heat pipe 10 of a first preferred embodiment of the present disclosure includes a pipe body 11, a second capillary structure 21 and a working fluid.

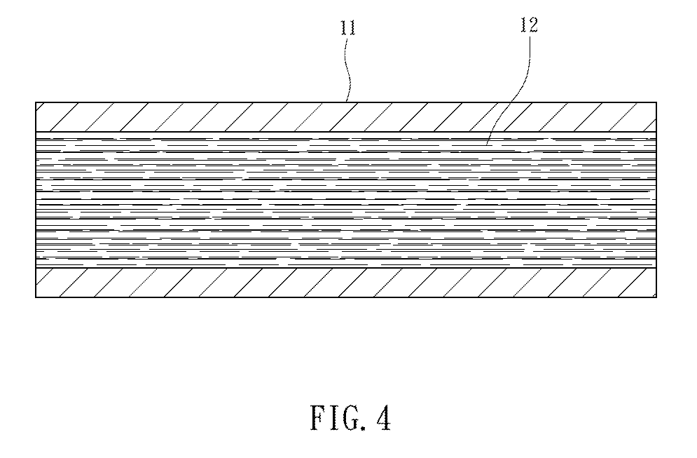

The pipe body 11 has two enclosed ends and is defined along the body part thereof from one enclosed end to the other enclosed end with a heat absorbing section H, a heat isolating section A and a condensing section C. The pipe body 11 has etched patterns located on an inner pipe wall thereof. The etched patterns, which serve as a first capillary structure 12, are fully distributed in the heat absorbing section H, the heat isolating section A and the condensing section C. In the first embodiment, the first capillary structure 12 is formed in a way that etchant flows through the pipe body 11 to etch the inner pipe wall of the pipe body 11 for forming the etched patterns with regular arrangement in the flowing direction of the etchant. Therefore, the first capillary structure 12 is the etched patterns with regular arrangement, as shown in FIG. 4. In addition, in the first embodiment, the diameter of the pipe body 11 is smaller than or equal to 3 mm; preferably, the diameter can be 2 mm, for example.

The second capillary structure 21 is disposed inside the pipe body 11 and located in the heat absorbing section H of the pipe body 11. The heat absorbing section H is filled up with the second capillary structure 21 which is capable of absorbing liquid by capillary action. In the first embodiment, the second capillary structure 21 formed by sintering of the copper powder is taken as example. Unlike the traditional heat pipe having pipe-shaped capillary structure which is sintered along the pipe wall and has a circular cross-section, the second capillary structure 21 filled in the heat absorbing section H fully can absorb more working fluid. More particularly, under a condition that the pipe body 11 is thinner and the internal space of the thin pipe body 11 is very small, the amount of the working fluid which can be injected into the pipe body 11 is relatively less, so it is hard to keep a certain quantity of the working fluid in the pipe body 11 during the whole manufacturing process. The second capillary structure 21 of the present disclosure is filled in the heat absorbing section H fully, so as to effectively form an enormous capillary structure and receive sufficient amount of the working fluid.

The working fluid is injected into the pipe body 11. In the first embodiment, pure water is taken as an example for the working fluid, but the present disclosure is not limited thereto. The working fluid can also be other liquid having similar function. The working fluid is an essential element of the conventional heat pipe, and other species or components of liquids are also well known by skills in this field, so their detailed description is omitted. The state of the working fluid staying in the pipe is hard to be shown in a drawing, and the working fluid is a well-known element, so the working fluid is now illustrated in the drawings of the present disclosure.

The above description illustrates the structure of the first embodiment, and the working state of the first embodiment will be described below.

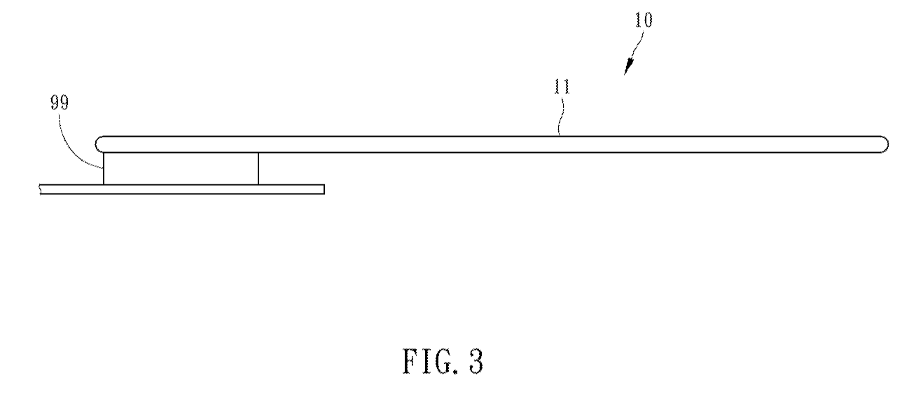

Referring to FIG. 3, before the present invention is in use, the heat absorbing section H is touched with a heat source 99, such as an electronic chip, a central processor or a battery. During operation, the working fluid received in the second capillary structure 21 is heated by the thermal energy generated by the heat source 99 into steam, the steam disperses to the condensing section C through the heat isolating section A in the pipe body 11 and is then condensed into liquid on the inner pipe wall of the condensing section C, and then guided backwards to the second capillary structure 21 through the first capillary structure 12. This heat exchange action is repeated again and again, thereby achieving the desired effect of transferring heat to the condensing section C.

In the first embodiment of the present disclosure, the first capillary structure 12 is the etched patterns formed on the inner pipe wall by etching, so it is not necessary to extra add a layer of copper powder or copper mesh on the inner pipe wall to forming the capillary structure, so that the problem in reduction of the pipe diameter due to the space inside the pipe occupied by the capillary structure can be prevented, and the first capillary structure 21 can perform well effect of guiding the working fluid backwards. In addition, in the first capillary structure 12, the capillary patterns formed by etching are very tiny, so the density of guiding paths and the capillary effect for guiding the working fluid backwards are better than the conventional pipe having the capillary structure composed of only grooves.

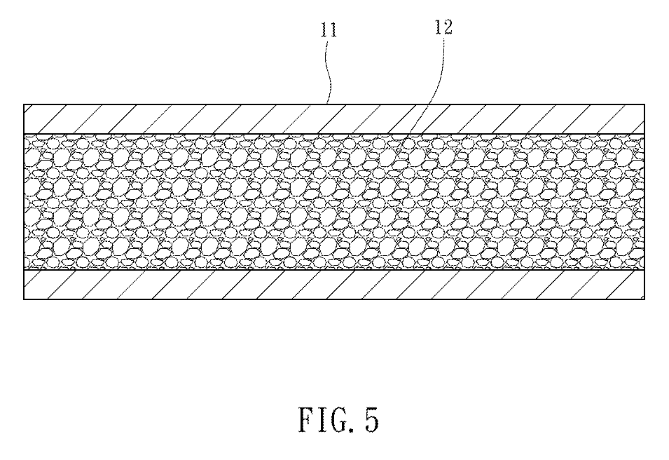

It should be complementarily illustrated that the first capillary structure 12 is not limited to the aforesaid etched patterns with regular arrangement, and may be the etched patterns with irregular arrangement as shown in FIG. 5. During the etching process, after the etchant is injected into the pipe body 11, the pipe body 11 is left to stand or shaken so that the inner pipe wall of the pipe body 11 can be etched to form the patterns with irregular arrangement to serve as the first capillary structure 12, and such first capillary structure 12 can similarly perform effect of guiding the working fluid backwards.

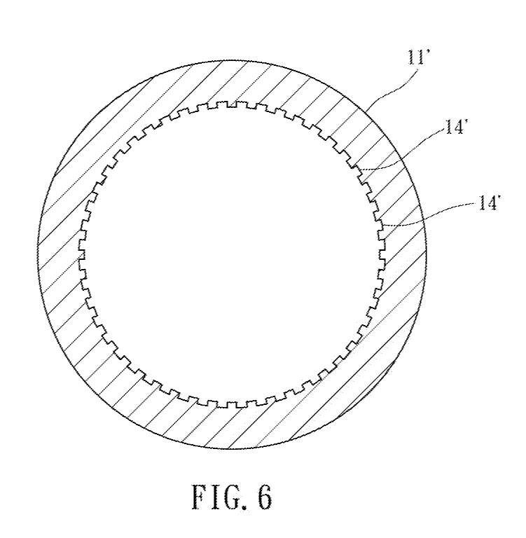

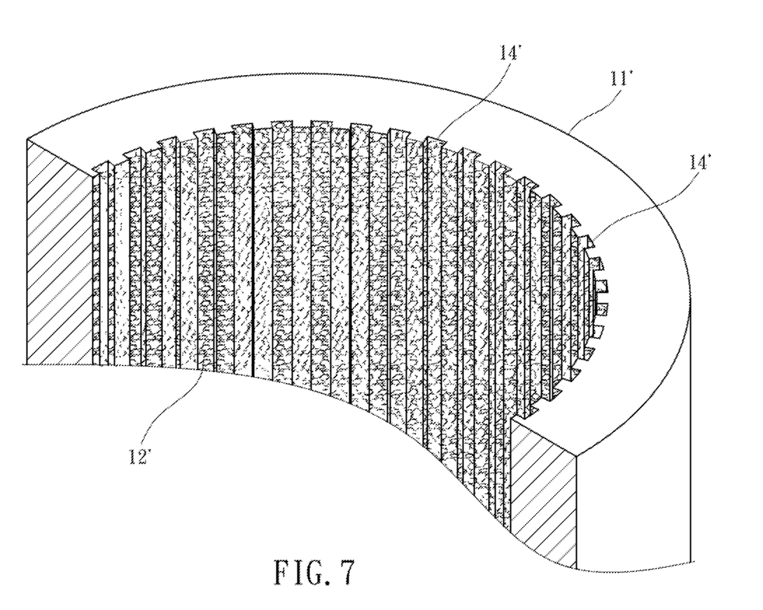

As shown in FIG. 6 and FIG. 7, the pipe body 11′ can be a pipe having grooves at the inside thereof, that is, the pipe body 11 is provided on the inner pipe wall thereof with a plurality of axially extended grooves 14′. The first capillary structure 12′ is not only distributed on the inner pipe wall, but also fully distributed on the inner walls of the grooves 14′. While the pipe body 11′ is the pipe having the grooves, the inner walls of the grooves 14′ are directly etched to form the above-mentioned structure. The capillary effect of the grooves 14′ plus that of the etched patterns can further improve the effect of guiding the working fluid backwards.

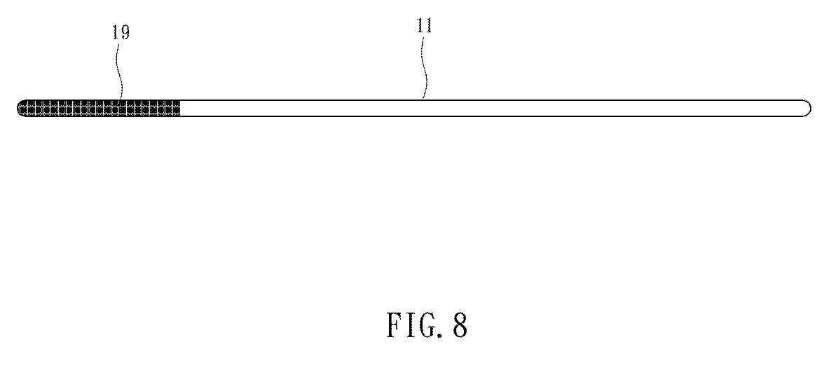

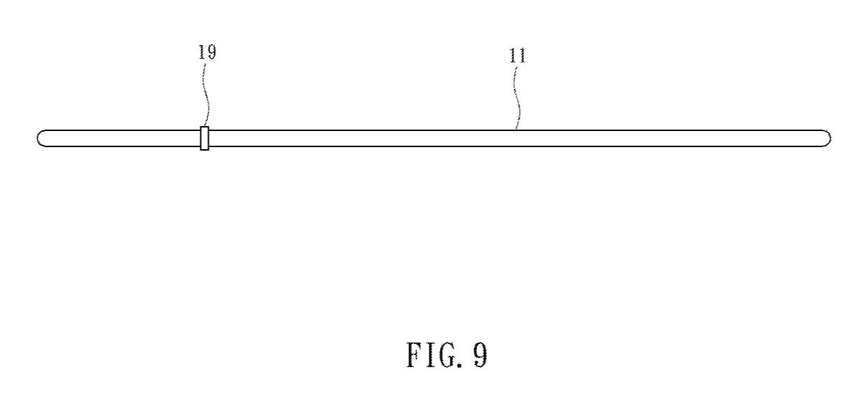

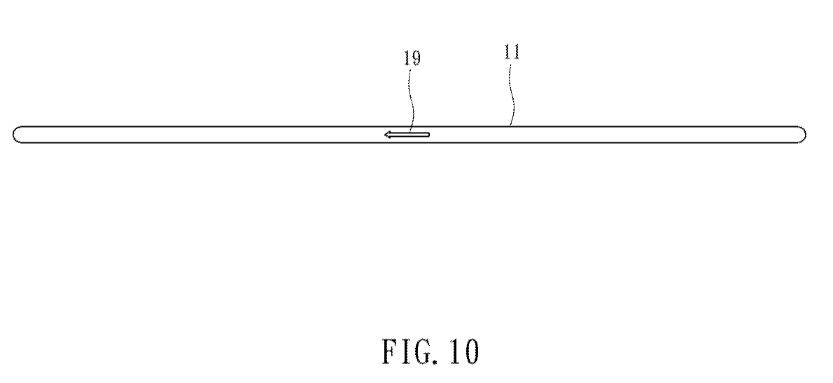

In the first embodiment, the second capillary structure 21 is only located in the heat absorbing section H and cannot be directly determined its location according to the appearance of the micro heat pipe 10. To improve that, a marker can be placed on the appearance of the micro heat pipe 10 to allow the user to directly determine the location of the heat absorbing section H. In practice, a marker 19 is disposed on an outer surface of the pipe body 11 for recognizing the location of the heat absorbing section H, so the user can determine the location of the heat absorbing section H of the micro heat pipe 10 according to the appearance of the micro heat pipe 10. As shown in FIG. 8, the disposal of the marker 19 can be formed by etching the outer surface of the pipe body 11, so the etched part has a rough matted surface in appearance. The etched part shown in the FIG. 8 is located at the heat absorbing section H of the micro heat pipe 10; alternately, the etched part can be at other locations, such as the condensing section C of the micro heat pipe 10. Alternately, the marker 19 can be a sleeve, as shown in FIG. 9; for example, the marker 19 can be a ring sleeved onto the pipe body 11. Alternately, as shown in FIG. 10, the marker 19 can be a coat of pigment applied on the outer surface of the pipe body 11. Alternately, the marker 19 can be a graph, such as an arrow, shown at any location on the surface of the pipe body 11 to indicate the location of the heat absorbing section H or the condensing section C. The aforesaid manners of setting the marker are taken as examples, but the present disclosure is not limited thereto.

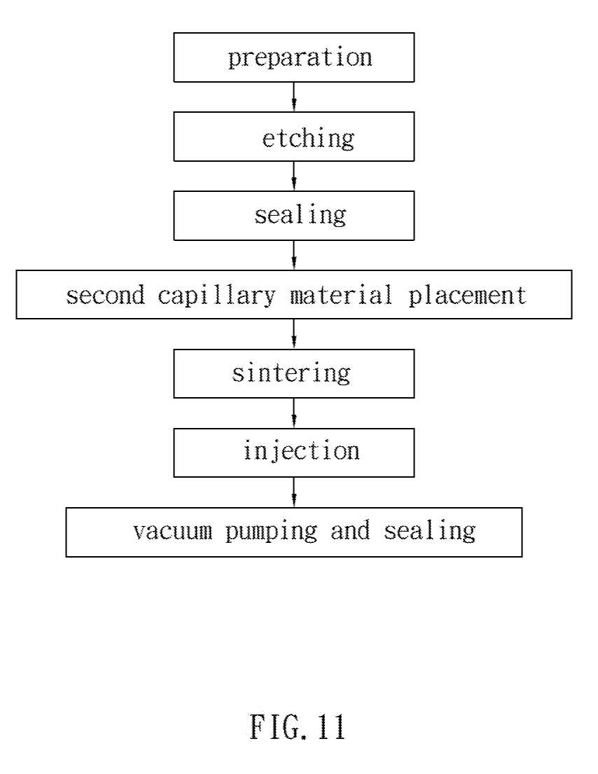

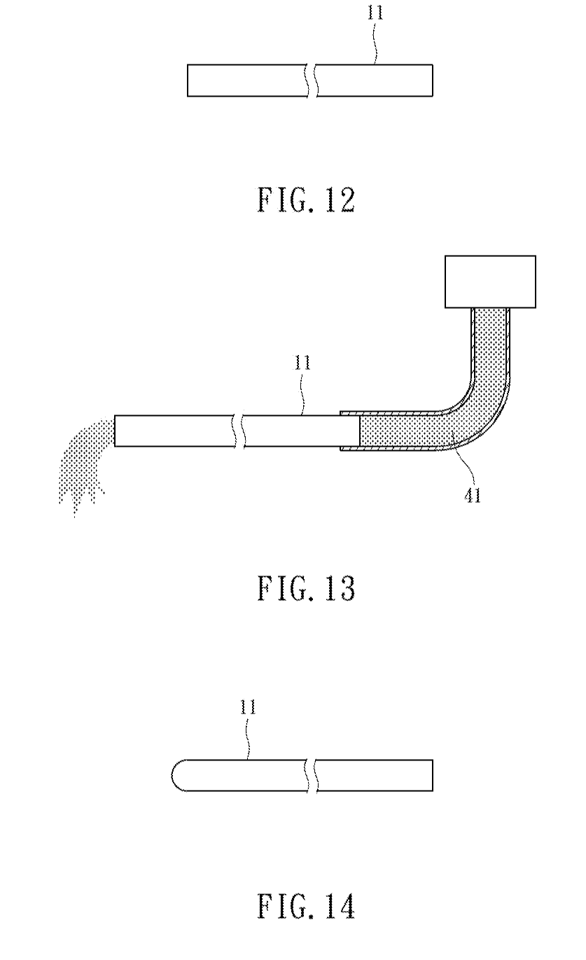

Please refer to FIG. 11 through FIG. 16, which illustrate a method of manufacturing the micro heat pipe according to a second preferred embodiment of the present disclosure. The elements shown in FIG. 12 through FIG. 16 are the same with that of the first embodiment, so the description below refers to the drawings and numbers the same with the first embodiment. The method of manufacturing the micro heat pipe includes the following steps.

A preparation step is shown in FIG. 12, wherein the pipe body 11 having two open ends is provided. In the second embodiment, the pipe body 11 has a diameter smaller than or equal to 3 mm; preferably, the diameter can be 2 mm as an example.

An etching step is shown in FIG. 13, wherein the etchant 41 is introduced into the pipe body 11 to etch the inner pipe wall of the pipe body 11, so as to form the etched patterns, which serve as the first capillary structure 12, on the inner pipe wall of the pipe body 11. During the etching process, the etching manners described in the first embodiment can be used to form the patterns with regular arrangement or irregular arrangement.

A sealing step is shown in FIG. 14, wherein an end of the pipe body 11 is sealed by solderless welding, and the heat absorbing section H, the heat isolating section A and the condensing section C are defined along the body part from the sealed end to the remained open end. In the solderless welding manner, the part of the pipe wall located at the open end of the pipe body 11 is melt to fuse together by spot welding, argon arc welding, or high energy welding, thereby achieving the effect of sealing.

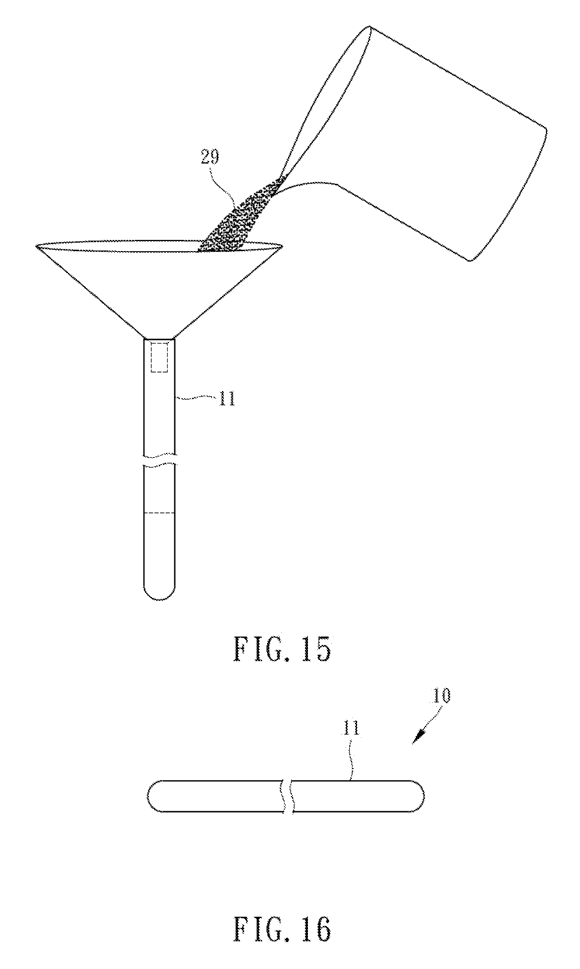

A second capillary material placement step is shown in FIG. 15, wherein the second capillary material 29 is placed into the pipe body 11 through the remained open end and located in the heat absorbing section H to make the heat absorbing section H filled up with the second capillary material 29. In the second embodiment, the second capillary material 29 is copper powder.

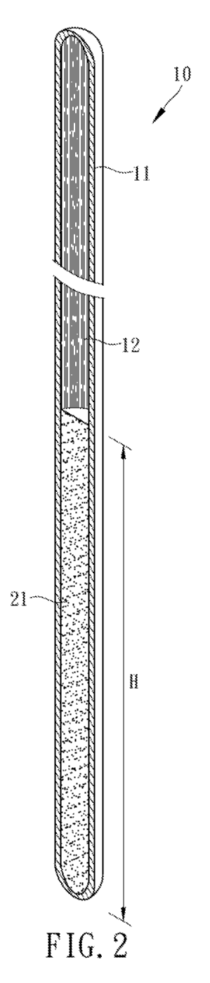

A sintering step is then performed in a way that the pipe body 11 is sintered with the second capillary material 29 so that the second capillary structure as shown in FIG. 2 is formed by the second capillary material.

An injection step is then performed in a way that the working fluid is injected into the pipe body 11. The injection technology is a well-known technology, so no drawing is used to illustrate it.

A vacuum pumping and sealing step is shown in FIG. 16, wherein the air is pumped out of the pipe body 11 to create a vacuum therein, and the remained open end of the pipe body 11 is then sealed by the aforesaid solderless welding manner. The technology of creating the vacuum is well known, so its detail description is omitted.

By performing the above-mentioned steps, the micro heat pipe 10 can be produced. The usage and effect of the micro heat pipe 10 produced by the aforesaid method are the same as that of the first embodiment, so the detailed description is omitted.

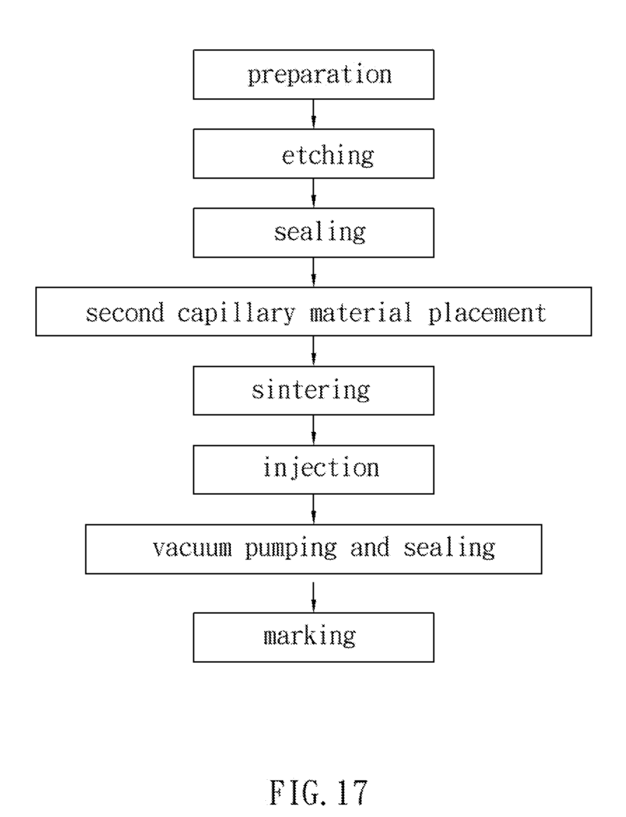

As shown in FIG. 17, the method provided in the second embodiment can further include a marking step to dispose the marker 19 on the outer surface of the pipe body 11, so as to allow the user to recognize the location of the heat absorbing section H. In this way, the user can determine the location of the heat absorbing section H of the micro heat pipe 10 according to the appearance of the micro heat pipe 10. The manner of disposing the marker 19 is illustrated in the first embodiment, so the detailed description is omitted.

In the second embodiment, the pipe body 11 prepared in the preparation step can be a pipe having grooves, that is, the pipe body 11 is provided on the inner pipe wall thereof with a plurality of axially extended grooves 14. In the etching step, the first capillary structure 12 is not only fully distributed on the inner pipe wall of the pipe body 11, but also fully distributed on the inner walls of the grooves 14.

What is claimed is:

1. A method of manufacturing a micro heat pipe, comprising the steps of:
preparing a pipe body having two open ends;
introducing etchant into the pipe body to etch an inner pipe wall of the pipe body to form etched patterns, which serve as a first capillary structure, on the inner pipe wall of the pipe body;
sealing one of the two open ends of the pipe body by solderless welding, and defining a heat absorbing section, a heat isolating section and a condensing section in order along a body part of the pipe body from the sealed end to the remained open end;
disposing a second capillary material through the remained open end in the heat absorbing section of the pipe body in a way that the second capillary material fills up the heat absorbing section;
sintering the second capillary material with the pipe body to make the second capillary material form a second capillary structure;
introducing a working fluid into the pipe body;
pumping air out of the pipe body to create a vacuum therein, and sealing the remained open end by solderless welding.

2. The method as claimed in claim 1, wherein, in the step of introducing the etchant into the pipe body, the etchant is arranged to flow through the pipe body to etch the inner pipe wall of the pipe body to form the etched patterns with regular arrangement along a flowing direction of the etchant.

3. The method as claimed in claim 1, wherein, in the step of introducing the etchant into the pipe body, the pipe body is filled up with the etchant and then left to stand for a period or shaken, so that the etched patterns are irregularly arranged on the inner pipe wall of the pipe body.

4. The method as claimed in claim 1, wherein the second capillary material is copper powder.

5. The method as claimed in claim 1, wherein the pipe body has a diameter smaller than 3 mm.

6. The method as claimed in claim 1, wherein, in the step of preparing the pipe body, the prepared pipe body is further provided on the inner pipe wall with a plurality of axially extended grooves.

7. The method as claimed in claim 6, wherein in the step of introducing the etchant into the pipe body, the first capillary structure is not only distributed on the inner pipe wall of the pipe body, but also fully distributed on inner walls of the grooves.

8. The method as claimed in claim 1, further comprising another step of disposing a marker on an outer surface of the pipe body for recognizing a location of the heat absorbing section.

9. The method as claimed in claim 8, wherein the marker is formed by etching the outer surface of the pipe body.

10. The method as claimed in claim 8, wherein the marker is one of a sleeve, which is sleeved onto the pipe body, and a coat of pigment, which is applied on the outer surface of the pipe body.
